(19) United States
(12) Patent Application Publication
(10) Pub. No.: US 2026/0334228 A1
(43) Pub. Date: Oct. 22, 2026

(54) METHODS AND APPARATUS TO PROTECT SOCKETS FOR INTEGRATED CIRCUIT PACKAGES FROM DAMAGE DURING SHOCK EVENTS

(71) Applicant: Intel Products IP LLC, Santa Clara, CA (US)

(72) Inventors: Daniel J. Neumann, Tualatin, OR (US); Min Pei, Camas, WA (US); Mohanraj Prabhugoud, Hillsboro, OR (US); Jordan Daniel Johnson, Lake Stevens, WA (US); Dawson Leander Willems, Newberg, OR (US)

(73) Assignee: Intel Products IP LLC, Santa Clara, CA (US)

(21) Appl. No.: 19/684,187

(22) Filed: May 21, 2026

(51) Int. Cl. H10W 40/60

(52) U.S. Cl. CPC H10W 40/60

(57) ABSTRACT

Systems, apparatus, articles of manufacture, and methods to protect sockets for integrated circuit packages from damage during shock events are disclosed. An example apparatus includes a heatsink to be thermally coupled to an integrated circuit package on a circuit board. The example apparatus includes a guidepost to protrude away from the circuit board into a hole in a base of the heatsink, a clearance between an outer surface of the guidepost and an inner sidewall of the hole being less than 0.5 mm.

### BACKGROUND

The demand for greater computing power and faster computing times continues to grow. This has led to higher-density connectors on computer hardware components to transfer signals more quickly. Some integrated circuit (IC) chips (e.g., land grid array (LGA) chips, pin grid array (PGA) chips, etc.) are communicatively coupled to printed circuit boards (PCBs) via sockets. Such sockets are constructed to receive and electrically couple to contacts on IC packages containing the chips. Often a heatsink is mechanically and thermally coupled to the IC chip on a side opposite the socket to facilitate the dissipation of heat generated by the chip. In some instances, the heatsink also provides a compressive load on the IC chip to ensure electrical connection between the chip and the associated socket.

### BRIEF DESCRIPTION OF THE DRAWINGS

FIG. 1 illustrates an exploded view of an example integrated circuit (IC) package heat-dissipating component stack constructed in accordance with teachings disclosed herein.

FIG. 2 is an enlarged view of the example component stack of FIG. 1 in assembled form.

FIG. 3 is a top view of the example component stack of FIGS. 1 and 2.

FIG. 4 is a cross-sectional side view of the example component stack of FIGS. 1-3 taken along the line 4-4 shown in FIG. 3.

FIG. 5 is an isometric view of one corner of the example component stack of FIGS. 1-4 with the fasteners and all associated hardware removed from the base of the example heatsink.

FIG. 6 is a top view of the base of the example heatsink of FIGS. 1-5 with example guideposts shown in respective holes.

FIG. 7 is a top view of another example heatsink with different-shaped holes to receive the example guideposts shown in FIGS. 1-6.

FIG. 8 is a top view of another example heatsink with different-shaped holes to receive the example guideposts shown in FIGS. 1-6.

FIG. 9 is a top view of another example heatsink with different-shaped holes to receive the example guideposts shown in FIGS. 1-6.

In general, the same reference numbers will be used throughout the drawing(s) and accompanying written description to refer to the same or like parts. The figures are not necessarily to scale.

### DETAILED DESCRIPTION

As integrated circuits, such as processor chips, continue to increase in size and power density, thermal management solutions (e.g., heatsinks) have also continued to increase in size. Known heatsinks are typically mounted to the backside of an integrated circuit (IC) package as part of an IC package heat-dissipating component stack (or simply “component stack” for short). Such component stacks often include a bolster plate that surrounds the IC package on a first side of a printed circuit board (PCB) with a backplate on the other side of the PCB, opposite the IC package. In some cases, a socket is positioned between the IC package and the PCB. Many sockets, including land grid array (LGA) sockets, include a plurality of pins that receive and electrically couple to corresponding features (e.g., contacts or lands) of the IC package. The bolster plate is typically attached to the backplate through the PCB. Further, the bolster plate is attached to the heatsink that extends over the IC package. More particularly, the heatsink is often connected to the bolster plate via spring-loaded fasteners that urge the heatsink and the bolster plate (with the backplate attached thereto) towards one another. This results in a compressive force that urges the heatsink towards the IC package, which is, in turn, urged towards the PCB. In cases where the IC package is inserted into a socket on the PCB, this compressive force is important to facilitate reliable electrical connection between the IC package and the socket. Further, regardless of whether there is a socket present, the compressive force generated by the fasteners connecting the heatsink to the bolster plate promotes reliable thermal coupling between the IC package and the heatsink.

High-performance processors with high thermal design power (TDP) require large and heavy thermal solutions (e.g., large and heavy heatsinks) to maintain safe operating temperatures. However, as heatsinks become larger and heavier, they pose an increasing risk of mechanical damage to the socket during shock events, such as those encountered during shipping. More particularly, larger and heavier heatsinks are a concern because the greater the mass of the heatsink, the greater the magnitude of shock-induced forces arising from movement of the heatsink relative to a socket and/or other components in a component stack. Such movement of a heavy heatsink relative to the socket can cause the socket to crack or break. Socket damage can render associated circuit boards unusable, thereby limiting the maximum allowable heatsink size and, consequently, the maximum cooling performance of the system.

Examples disclosed herein mitigate the above challenges to enable the use of larger and heavier heatsinks for improved cooling performance. More particularly, examples disclosed herein use guideposts extending from the bolster plate and/or backplate in a component stack to resist the movement of a heatsink during shock events. That is, the guideposts absorb shock-induced forces from the momentum of a heatsink in a shock event and transfer such forces to the bolster plate and/or backplate, thereby protecting the socket from damage.

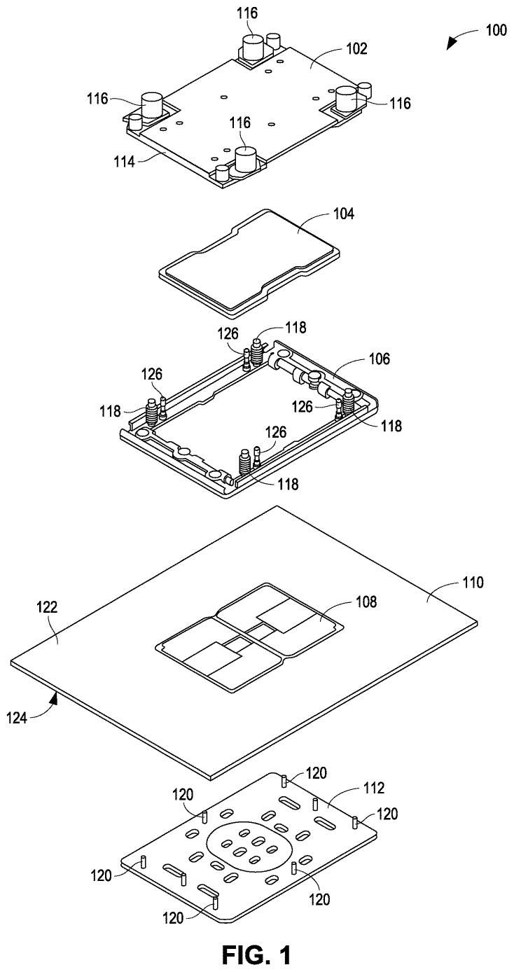

FIG. 1 illustrates an exploded view of an example integrated circuit (IC) package heat-dissipating component stack 100 (also referred to simply as a “component stack” for short) constructed in accordance with teachings disclosed herein. In FIG. 1, the component stack 100 includes a heatsink 102, an integrated circuit (IC) package 104, a bolster plate 106, a socket 108 coupled to a printed circuit board (PCB) 110 (e.g., a motherboard, a server board), and a backplate 112.

The IC package 104 includes one or more electrical circuits on a semiconductor substrate (e.g., of one or more semiconductor dies). The IC package 104 can perform processing functions, memory functions, and/or any other suitable functions. The IC package 104 can include any type of processing circuitry, including one or more programmable microprocessors, one or more field programmable gate arrays (FPGAs), one or more central processing units (CPUs), one or more graphics processing units (GPUs), one or more digital signal processors (DSPs), one or more XPUs, one or more application specific integrated circuits (ASICs), and/or one or more microcontrollers. In this example, the IC package 104 is a land grid array (LGA) processor chip. In other examples, the IC package 104 is a ball grid array (BGA) processor chip or a pin grid array (PGA) processor chip. Further, other types of IC packages can be used in the component stack 100 instead of a processor chip (e.g., a memory chip).

In this example, the heatsink 102 includes a base 114 that is to support an array of fins and/or one or more heat pipes to facilitate the dissipation of heat. For purposes of clarity, the fins and heat pipes are omitted in the illustrated examples. In some examples, the heatsink 102 is couplable (e.g., thermally couplable) to the IC package 104 to dissipate heat therefrom. More particularly, in some examples, the base 114 thermally couples with the IC package 104. In some examples, a thermal interface material (TIM) is disposed between the base 114 and the IC package 104.

In the illustrated example of FIG. 1, the heatsink 102 is mechanically coupled to the backplate 112 via loading fasteners 116 (e.g., fixture elements, loading mechanisms). In some examples, the heatsink 102 is coupled to the backplate 112 via the bolster plate 106 positioned therebetween. More particularly, in some examples, the loading fasteners 116 on the heatsink 102 engage with loading posts 118 (e.g., first posts) on the bolster plate 106. The bolster plate 106, in turn, engages with studs 120 (e.g., second posts) on the backplate 112. As shown in the illustrated example, the bolster plate 106 is coupled to the backplate 112 with the PCB 110 sandwiched therebetween. Specifically, the bolster plate 106 is coupled to a top surface 122 of the PCB 110 (e.g., around the socket 108 that is also on the top surface 122 of the PCB), and the backplate 112 is coupled to a bottom surface 124 of the PCB 110 opposite the bolster plate 106 in the orientation shown in FIG. 1. Based on this arrangement, tightening of the loading fasteners 116 places the components between the heatsink 102 and the backplate 112 within the component stack 100 in compression. In particular, as the heatsink 102 is urged towards the backplate 112, the heatsink 102 presses the IC package 104 towards the socket 108.

In this example, the socket 108 communicatively couples the IC package 104 to the PCB 110. In some examples, the socket 108 is a land grid array (LGA) socket, which includes a plurality of pins within the socket arranged to interface (e.g., electrically couple) with corresponding contacts or lands on the IC package 104. In other examples, the socket 108 can be implemented by any other suitable type of socket (e.g., a ball grid array, a pin grid array, etc.) suitable to receive and interface with the IC package 104. The compression created by the mechanical coupling of the heatsink 102 to the backplate 112 via the loading fasteners 116 serves to ensure that corresponding connectors (e.g., pins, lands, etc.) on the socket 108 and the IC package 104 remain in contact.

As noted above, as IC packages 104 increase in size, there is a need for a corresponding increase in size of heatsinks 102 used to cool such IC packages 104. The larger size of heatsinks 102 results in an increase in the overall mass of such heatsinks 102, which leads to increases in the magnitude of shock-induced forces from the heatsinks 102 acting on the other components of the component stack 100 during shock events. The relatively large forces produced by heavy heatsinks during shock events create a concern for potential damage to the socket 108. In the past, one approach to solve this problem has been to limit the size of heatsinks. However, this is not a viable option for modern high performance computing applications because smaller heatsinks do not provide adequate cooling. Another option is to decouple the IC package 104 from the heatsink 102 through the implementation of an independent loading mechanism (ILM). While this option reduces the risk of damage to the socket 108, this approach frequently results in bent pins and limits the size of IC packages 104, which, again, is not a viable alternative to meet modern high performance computing requirements. A third option to reduce (e.g., minimize) heatsink 102 movement during shock events is to increase the socket load. However, this approach increases stress on the socket 108, the loading fasteners 116 and the associated loading posts 118, and the IC package 104. Thus, increasing the socket load comes with tradeoffs that are unacceptable in many situations.

Examples disclosed herein mitigate the above concerns through the use of guideposts 126 (e.g., third posts, guide pins) on the bolster plate 106. Specifically, in the illustrated example, the guideposts 126 protrude upwards from the bolster plate 106 and extend into (e.g., through) corresponding holes in the base 114 of the heatsink 102. Guideposts have been used in the past to assist in positioning a heatsink on top of other components in a component stack. However, unlike known guideposts, the example guideposts 126 of the illustrated example are structured and positioned relative to the corresponding holes in the heatsink 102 to resist and/or restrict movement of the heatsink 102 during shock events. More particularly, in some examples, the guideposts 126 are larger than known guideposts to provide more strength and ability to absorb shock-induced forces by transferring such forces to the bolster plate. Further, in some examples, the guideposts 126 are dimensioned and positioned to maintain a tight clearance with the holes in the heatsink 102 through which the guideposts 126 extend. Experimental testing has revealed that a clearance of less than 0.5 millimeters (mm) significantly restricts the ability of the heatsink 102 to move relative to the socket 108. As a result, such a tight clearance has been shown to provide a significant reduction in damage to sockets 108 when the component stack 100 is subject to a shock event. In some examples, the clearance between the guideposts 126 and the corresponding holes in the heatsink 102 is even less than 0.5 mm (e.g., less than or equal to 0.45 mm, less than or equal to 0.4 mm, etc.).

Notably, such tight clearances can present challenges for assembling the component stack 100. More particularly, if the clearance gets too small, there is a risk of the heatsink 102 binding on the guideposts 126, thereby preventing the heatsink 102 from being properly seated on top of the IC package 104. Experimental testing has been performed with clearances as low as 0.25 mm, which offer even greater protection against shock events than using the larger clearances noted above. However, the challenges of assembling the component stack 100 at such tight clearances often outweigh the benefits provided during shock events. Accordingly, in some examples, the tight clearance between the guideposts 126 and the corresponding holes in the heatsink 102 is at least 0.25 mm. In some examples, to ensure greater ease in assembly, the guideposts 126 are positioned and dimensioned with a lower limit on the clearance that is greater than 0.25 mm (e.g., at least 0.3 mm, at least 0.315 mm, etc.).

In some examples, the guideposts 126 protrude from the backplate 112 instead of the bolster plate 106. That is, in some examples, the guideposts 126 extend through holes in the PCB 110 and the bolster plate 106. In some examples, some of the guideposts 126 protrude from the backplate 112 while other guideposts 126 protrude from the bolster plate 106.

In some examples, the guideposts 126 are made of a material that is stiffer and/or stronger than the material of the socket 108. As such, the guideposts 126 have a greater ability to withstand shock-induced forces without failing. More particularly, in some examples the guideposts 126 are made of metal. In some examples, the guideposts 126 are made of the same metal used for the bolster plate 106 and/or the backplate 112 to which the guideposts 126 are attached. In other examples, the guideposts 126 are made from a metal that is different from the bolster plate 106 and/or the backplate 112.

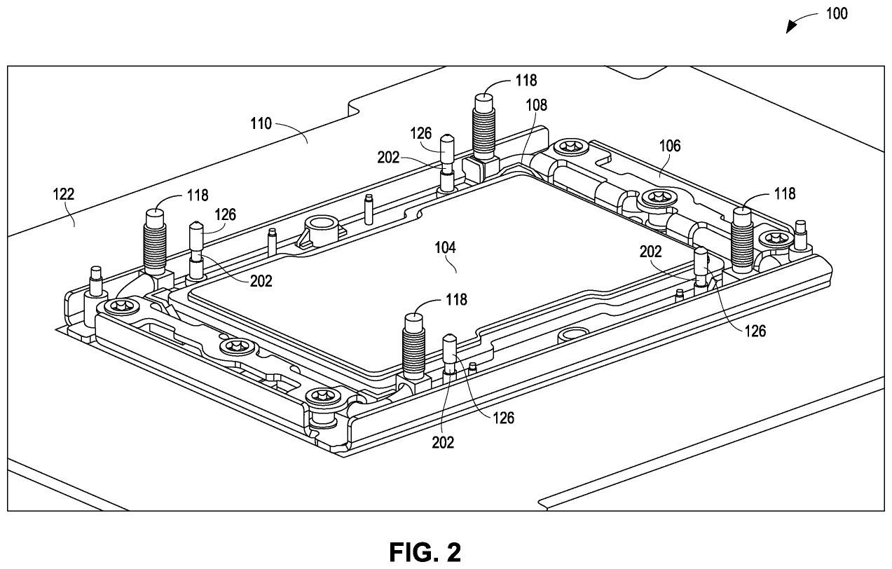

FIG. 2 is an enlarged view of the example component stack 100 of FIG. 1 in assembled form. In the illustrated example of FIG. 2, the heatsink 102 is omitted to provide a better view of the other components. As shown in the illustrated example, the IC package 104 is positioned on top of the socket 108, which is surrounded by the bolster plate 106. In this example, the guideposts 126 are adjacent to the loading posts 118. In other examples, the loading posts 118 and/or the guideposts 126 can be in any other suitable location. Further, although four guideposts 126 are shown, in other examples, a larger or smaller number of guideposts 126 may be used. In the illustrated example, the guideposts 126 include a narrow neck 202 between opposing ends of the guideposts 126. However, in other examples, the narrow necks 202 are omitted and the guideposts 126 have a straight outer profile along their lengths.

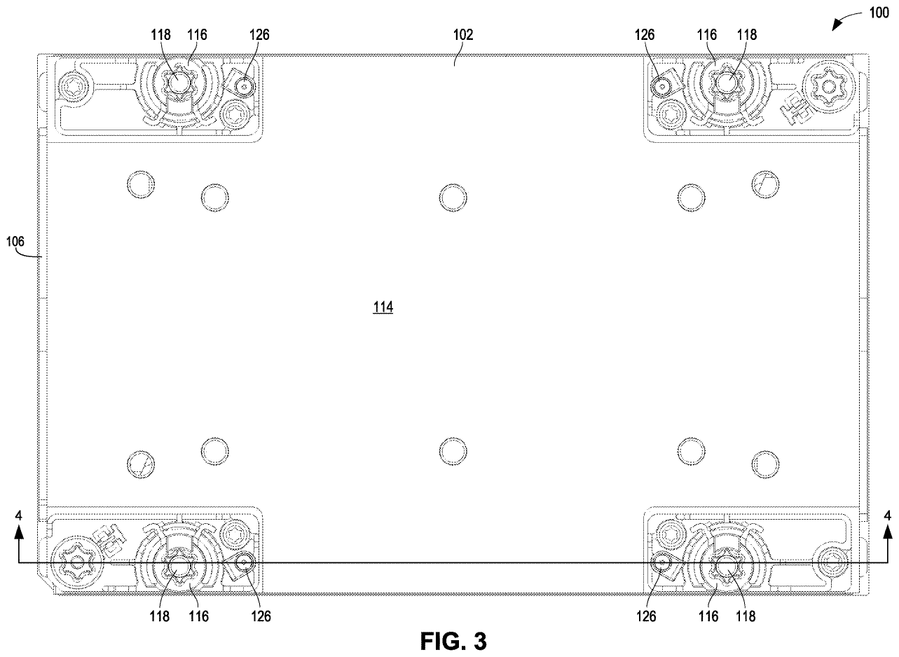

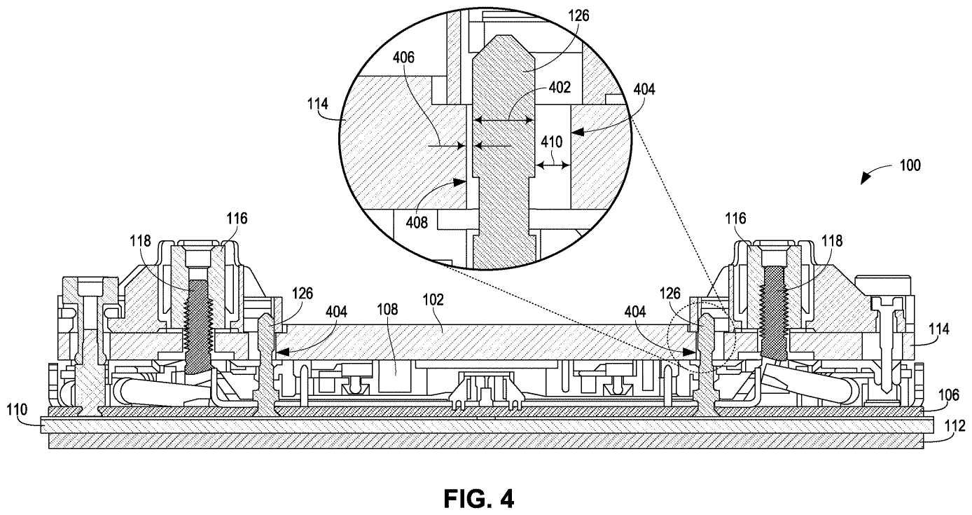

FIG. 3 is a top view of the example component stack 100 of FIGS. 1 and 2 in assembled form. FIG. 4 is a cross-sectional side view of the example component stack 100 taken along the line 4-4 shown in FIG. 3. As shown in FIG. 3, the line 4-4 passes through the center of two of the guideposts 126. In the illustrated example of FIG. 4, the cross-hatching used for the guideposts 126 is different from the cross-hatching used for the bolster plate 106 for purposes of visual distinction. In some examples, as noted above, the guideposts 126 are made of the same material as the bolster plate 106. In some examples, the guideposts 126 are an integral extension of the bolster plate 106. However, in the illustrated example, the guideposts 126 are separate metal features that are attached to the bolster plate 106. Accordingly, in some examples, the material of the guideposts 126 is different from the material of the bolster plate 106. In some examples, the guideposts 126 are press-fit into corresponding openings in the bolster plate 106. In other examples, the guideposts 126 can be attached to the bolster plate 106 in any other suitable matter (e.g., with an adhesive, via welding, etc.). Any suitable mode of attachment may also be used in examples where the guideposts 126 are connected directly to the backplate 112 instead of the bolster plate 106.

In some examples, the guideposts 126 have a width 402 (e.g., diameter) of at least 2.5 mm. In some examples, the width 402 is greater than 2.5 mm (e.g., at least 2.75 mm, at least 2.9 mm, at least 3 mm, at least 3.1 mm, etc.). The width 402 of the guideposts 126 is greater than the width of many known guideposts because the guideposts 126 of the illustrated example do more than merely guide the heatsink 102 into alignment with the bolster plate 106 and the socket 108. Specifically, in some examples, the guideposts 126 serve the function of restraining lateral movement of the heatsink 102 during a shock event. Regardless of the strength of the guideposts 126, the guideposts 126 will not be able to restrain movement of the heatsink 102 sufficiently to protect the socket 108 if there is too much clearance between the guideposts 126 and the heatsink 102. Accordingly, to inhibit lateral movement of the heatsink 102, the example guideposts 126 are positioned to extend into corresponding holes 404 (e.g., openings, apertures) in the base 114 of the heatsink 102 with a relatively tight clearance 406 (e.g., clearance gap, clearance distance). More particularly, as labelled in the inset image in FIG. 4, the clearance 406 corresponds to the distance between the guidepost 126 and an inner sidewall 408 of the holes 404 through which the guidepost 126 extends. In some examples, the clearance 406 is between approximately 0.315 mm and 0.45 mm. In some examples, the clearance 406 may be lower than 0.315 mm (e.g., as low as 0.25 mm). However, there are tradeoffs with decreasing the clearance below 0.315 mm because such small clearances can create difficulties when the component stack 100 is being assembled. Likewise, in some examples, the clearance 406 may be greater than 0.45 mm (e.g., as high as 0.5 mm or higher). However, the effectiveness of the guideposts 126 to adequately limit lateral movement of the heatsink 102 diminishes as the clearance 406 becomes larger.

In this example, the holes 404 extend all the way through the base 114 of the heatsink 102 (e.g., from a bottom side to a top side). Further, in this example, the guideposts 126 also extend an entire way through the base 114 so as to protrude beyond the top side of the base 114. In other examples, the guideposts 126 extend into the holes 404 (from the bottom side of the base 114) without extending beyond the top side of the base 114. In some examples, the holes 404 do not extend all the way through the base 114. Rather, in such examples, the holes 404 are blind holes on the bottom side of the base 114 and the guideposts 126 are dimensioned to extend into such blind holes without hitting the end of such holes.

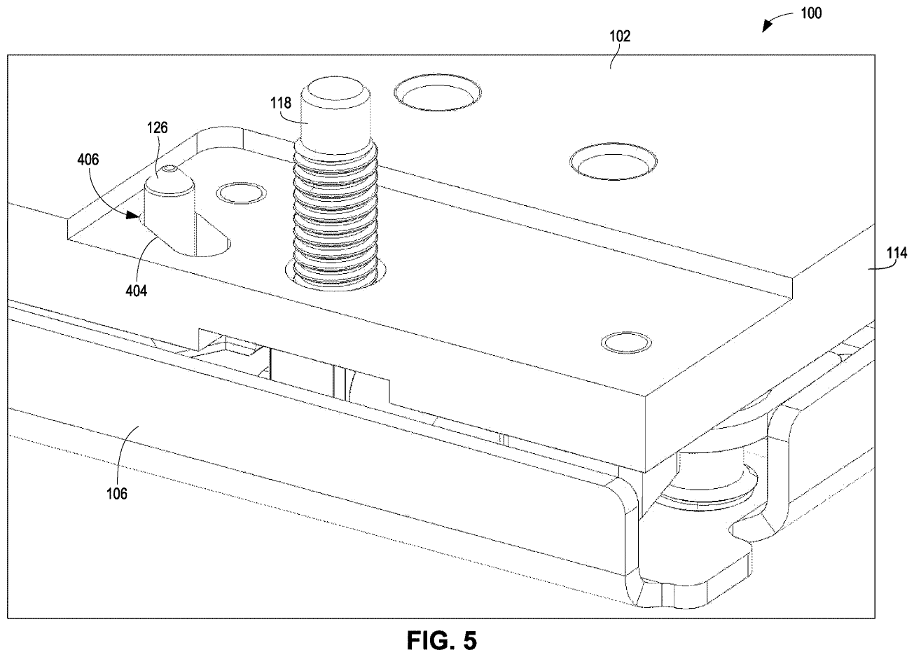

In some examples, the relatively tight clearance 406 between the guidepost 126 and the hole 404 is not consistent all the way around the perimeter of the guidepost 126. That is, in some examples, the guidepost 126 is closer to one portion of the sidewall 408 of the hole 404 (e.g., the left side of the hole in the enlarged inset image in FIG. 4) than the guidepost 126 is to another portion of the sidewall 408 (e.g., the right side of the hole 404 in the enlarged inset image in FIG. 4). For instance, as shown in FIG. 4, there is a distance of separation 410 between the guidepost 126 and a portion of the sidewall 408 that is larger than the tight clearance 406. In some examples, the distance of separation 410 is significantly larger (e.g., at least twice as large, at least five times as large, at least an order of magnitude larger, etc.). In such examples, the relatively tight clearance 406 corresponds to the shortest distance between the guidepost 126 and the corresponding hole 404. In some examples, the distance of separation 410 being larger than the tight clearance 406 is due to the guidepost being shifted off-center within the hole 404. In some examples, the off-centered position of the guidepost 126 relative to the hole 404 is because the guidepost 126 is round, while the hole 404 is an elongated slot. This is shown more clearly in FIG. 5, which is a detailed isometric view of one corner of the example component stack 100 with the loading fasteners 116 and all associated hardware removed from the base 114 of the heatsink 102. As shown in FIG. 5, the hole 404 is an elongated slot and the guidepost 126 is adjacent to one end of the hole 404 where the relatively tight clearance 406 is provided.

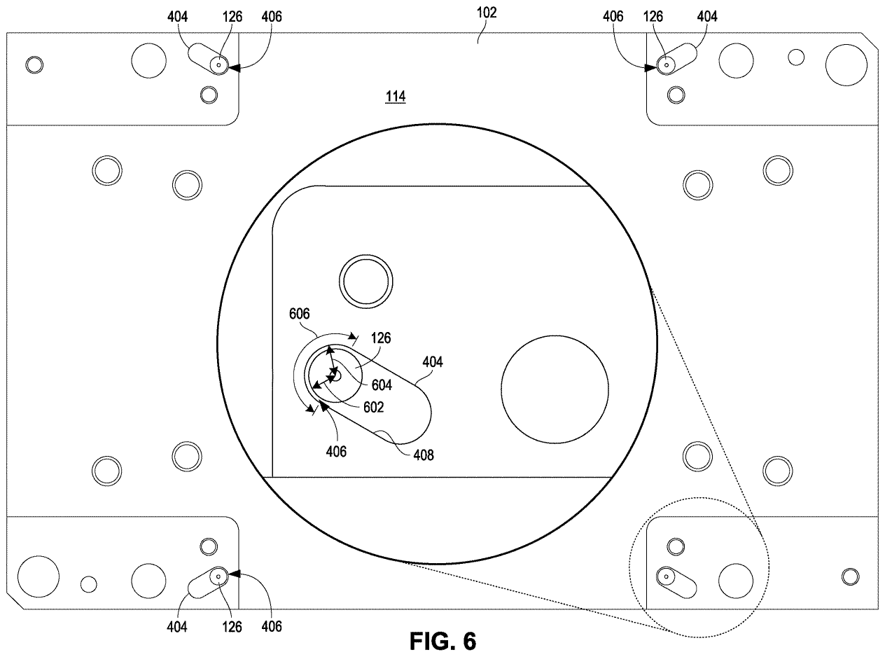

Even though the guideposts 126 of the illustrated example do not have a tight clearance 406 with the corresponding holes 404 on all sides, the positions of the separate guideposts 126 to their respective holes 404 are sufficient to limit movement of the heatsink 102 in any lateral direction. For instance, as shown in the illustrated example of FIG. 4, the guidepost 126 on the left has the tight clearance 406 on the right side of the guidepost 126 to inhibit lateral movement of the heatsink 102 towards the left. By contrast, the guidepost 126 on the right in FIG. 4 has the tight clearance 406 on the left side of the guidepost 126 to inhibit lateral movement of the heatsink 102 towards the right. As a result, the two guideposts 126 shown in the illustrated example can work together to inhibit movement of the heatsink 102 either to the left or the right in the plane of the drawing shown in FIG. 4. Lateral movement into and out of the page in FIG. 4 is achieved by the guideposts 126 shown in FIG. 4 in combination with the other guideposts 126 extending through the base 114 of the heatsink 102 as more clearly shown in FIG. 6.

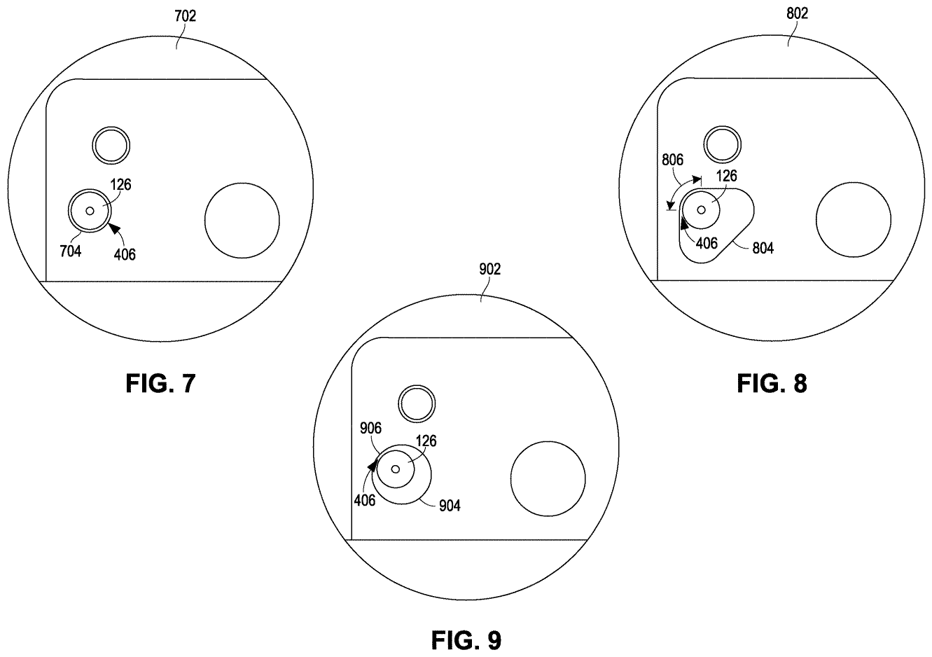

FIG. 6 is a top view of the base 114 of the heatsink 102 with the guideposts 126 positioned in respective holes 404. All other features of the component stack 100 of FIGS. 1-5 are omitted from FIG. 6 for purposes of clarity and explanation. As labeled in the enlarged inset image provided in FIG. 6, the relatively tight clearance 406 is defined by the difference between a first radius 602 of the guideposts 126 and a second (larger) radius 604 corresponding to a portion of the sidewall 408 of the hole 404 that follows a circular arc. In this example, the circular arc of the sidewall 408 is concentric with the guideposts 126. As a result, the tight clearance extends continuously along a length 606 of the circular arc, which corresponds to 180 degrees around the guideposts 126 in this example. In other words, the tight clearance 406 extends along one half of a full circumference of the guideposts 126. Thus, in some examples, the tight clearance 406 extends less than 360 degrees around the guidepost 126. In other examples, the length 606 of the circular arc (e.g., the proportion of the circumference of the guideposts 126 associated with the tight clearance 406) can be greater or less than 180 degrees as discussed further below in connection with FIGS. 7-9.

As shown in the illustrated example, the orientation of the region of the tight clearance 406 (e.g., the rotational orientation of the length 606 of the circular arc) relative to each corresponding guidepost 126 is different from the orientation of the region of the clearance 406 associated with the other guideposts 126. Specifically, in this example, the clearance 406 of the upper left guidepost in FIG. 6 is oriented towards the bottom right corner of the figure, the clearance 406 of the upper right guidepost is oriented towards the bottom left corner, the clearance 406 of the bottom left guidepost is oriented towards the upper right corner, and the clearance 406 of the bottom right guidepost is oriented towards the upper left corner. In other words, in this example, the clearance 406 associated with each guidepost 126 is oriented towards the center of the heatsink 102. The reason for the different orientations is to ensure that lateral movement of the heatsink 102 in any direction is inhibited by at least one of the guideposts 126. In other words, in some examples, the guideposts 126 are positioned relative to the holes 404 so that regions of the clearance 406 associated with different guideposts 126 are complementary to one another (e.g., points along the regions of the clearance 404 are on opposite sides of two different guideposts 126 or otherwise positioned to relative to three or more guideposts 126 to collectively to inhibit movement in any direction). Subject to this constraint, the orientations of the different regions of the clearance 406 associated with the different guideposts 126 can be different from what is shown in FIG. 6. For instance, the clearance regions can be oriented away from the center of the heatsink 102. In other examples, any other suitable orientation can be used.

The complementary nature of the regions of the clearance 406 associated with the different guideposts 126 depends on the guideposts 126 being rigidly fixed in position relative to one another so that the guideposts 126 can be properly positioned within each of the different holes 404 (which are also rigidly fixed in position relative to one another). Although the clearance 406 for each guidepost 126 may be designed to be the same, each clearance 406 may not be exactly the same when the component stack 100 is assembled due to misalignments. For instance, if the heatsink 102 is shifted slightly to the left in FIG. 4 such that the inner sidewall of the hole 404 is in contact with (e.g., abutting) the guidepost 126 shown on the left in the figure, then the clearance 406 associated with the guidepost 126 shown on the right will be larger than what is illustrated. Thus, the example limits for the clearance 406 outlined above (e.g., between 0.25 mm and 0.5 mm) assume the guideposts 126 are concentrically aligned with the circular arc portion of the associated holes 404. In actual implementation, the clearance can theoretically be reduced to zero at a first location associated with one guidepost 126 (if the heatsink is shifted to abut the guidepost) and doubled at a second complementary location associated with another guidepost 126. In such examples, regardless of any misalignment, the sum of the two clearance dimensions will be less than twice the upper limit (e.g., less than 2×0.5 mm=1.0 mm).

FIG. 7 is a top view of another example heatsink 702 with a different-shaped hole 704 to receive the guideposts 126 of FIGS. 1-6. Specifically, in the illustrated example of FIG. 7, the hole 704 is circular and concentrically aligned with the guidepost 126. As a result, the tight clearance 406 extends around the entire circumference of the guidepost 126. That is, the circular arc of the sidewall of the hole 704 extends a full 360 degrees around the guidepost 126. As a result, in this example, the guidepost 126 can resist movement of the heatsink 702 in any lateral direction without working in combination with other guideposts 126. In some examples, the heatsink 702 may still engage multiple guideposts 126 to distribute the associated forces across more than one guidepost 126.

FIG. 8 is a top view of another example heatsink 802 with a different-shaped hole 804 to receive the guideposts 126 of FIGS. 1-6. Specifically, in the illustrated example of FIG. 8, the hole 804 includes a sidewall that follows a circular arc concentrically aligned with the guidepost 126 along a length 806 corresponding to 90 degrees around the guidepost 126. Thus, in this example, the tight clearance 406 extends one fourth of the way around the entire circumference of the guidepost 126.

FIG. 9 is a top view of another example heatsink 902 with a different-shaped hole 904 to receive the guideposts 126 of FIGS. 1-6. Specifically, in the illustrated example of FIG. 9, the hole 904 is circular and significantly larger than the guidepost 126. Further, unlike the previous examples, in the illustrated example of FIG. 9, the circular arc of the hole 904 is not concentrically aligned with the guidepost 126. Rather, the guidepost 126 is positioned closer to a first point 906 along the sidewall of the hole 904 and farther from every other point along the sidewall. Thus, in this example, the tight clearance 406 (e.g., the shortest distance between the guidepost 126 and the sidewall of the hole 904) is at the first point 906.

The foregoing examples of the heatsinks 102, 702, 802, 902 with the associated holes 404, 704, 804, 904 to receive the example guideposts 126 of FIGS. 1-9 teach or suggest different features. Although each example heatsink 102, 702, 802, 902 and associated holes 404, 704, 804, 904 disclosed above has certain features, it should be understood that it is not necessary for a particular feature of one example to be used exclusively with that example. Instead, any of the features described above and/or depicted in the drawings can be combined with any of the examples, in addition to or in substitution for any of the other features of those examples. One example's features are not mutually exclusive to another example's features. Instead, the scope of this disclosure encompasses any combination of any of the features. Furthermore, the number, size, shape, and/or position of the holes 404, 704, 804, 904 as well as the number, size, shape, and/or position of the corresponding guideposts 126 can differ in any suitable manner from what is specifically shown in the figures described above.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that enable the use of heatsinks that are larger than previously possible for improved cooling performance, thereby enabling the implementation of processor chips with higher thermal design powers than previously possible. The size of heatsinks has been limited in the past because the associated mass of large heatsinks results in relatively large forces being transferred to sockets during shock events that can cause damage to the sockets. Examples disclosed herein resist such shock-induced forces through the use of guideposts that are positioned to extend into holes in a heatsink with relatively tight clearances. The tight clearances inhibit lateral movement of the heatsink, thereby protecting the socket from damage.

Further examples and combinations thereof include the following:

Example 1 includes an apparatus comprising a heatsink to be thermally coupled to an integrated circuit package on a circuit board, and a guidepost to protrude away from the circuit board into a hole in a base of the heatsink, a clearance between an outer surface of the guidepost and an inner sidewall of the hole being less than 0.5 mm.

Example 2 includes the apparatus of any preceding clause, including a bolster plate to surround the integrated circuit package, the guidepost connected to and protruding from the bolster plate.

Example 3 includes the apparatus of any preceding clause, including a backplate adjacent to a back side of the circuit board, the circuit board between the backplate and the heatsink, the guidepost connected to and protruding from the backplate through the circuit board.

Example 4 includes the apparatus of any preceding clause, wherein the guidepost has a first radius, and the inner sidewall follows a circular arc having a second radius, the clearance corresponding to a difference between the first radius and the second radius.

Example 5 includes the apparatus of any preceding clause, wherein the circular arc extends less than 360 degrees around a circumference of the guidepost.

Example 6 includes the apparatus of any preceding clause, wherein the circular arc extends 180 degrees or less around the circumference.

Example 7 includes the apparatus of any preceding clause, wherein the circular arc extends at least 90 degrees around a circumference of the guidepost.

Example 8 includes the apparatus of any preceding clause, wherein the guidepost is a first guidepost, the hole is a first hole, and the clearance is a first clearance, the apparatus including a second guidepost that is to extend into a second hole in the base of the heatsink, a second clearance between an outer surface of the second guidepost and an inner sidewall of the hole being less than 0.5 mm.

Example 9 includes the apparatus of any preceding clause, wherein the first and second clearances are to be at complementary locations relative to the respective first and second guideposts.

Example 10 includes the apparatus of any preceding clause, wherein both the first and second clearances are to be oriented towards a center of the base of the heatsink.

Example 11 includes the apparatus of any preceding clause, wherein the hole is an elongated slot.

Example 12 includes the apparatus of any preceding clause, wherein the guidepost is to be adjacent to a first end of the elongated slot.

Example 13 includes the apparatus of any preceding clause, wherein the guidepost has a width of approximately 3 mm.

Example 14 includes an apparatus comprising a heatsink, a first pin to extend into a first hole in a base of the heatsink, the first pin to be a first distance from a first point along an inner sidewall of the first hole, and a second pin rigidly fixed in position relative to the first pin, the second pin to extend through a second hole in the heatsink base, the second pin to be a second distance from a second point along an inner sidewall of the second hole, a sum of the first distance and the second distance to be less than 1 mm.

Example 15 includes the apparatus of any preceding clause, wherein the first point is on a first side of the first pin, and the second point is on a second side of the second pin, the first side opposite to the second side.

Example 16 includes the apparatus of any preceding clause, wherein the first pin is to be a third distance from a third point along the inner sidewall of the first hole, the third point spaced apart from the first point, the third distance greater than the first distance.

Example 17 includes an apparatus comprising a socket mounted to a circuit board, a bolster plate mounted on the circuit board adjacent to the socket, a backplate coupled to the bolster plate, the circuit board between the backplate and the bolster plate, a heatsink to be thermally coupled to an integrated circuit package in the socket, and a post extending into opening in the heatsink, the post extending from at least one of the bolster plate or the backplate, the post having a clearance gap with a sidewall of the opening that is 0.45 mm or less.

Example 18 includes the apparatus of any preceding clause, wherein the clearance gap is to extend along a first proportion of a circumference of the post, a second proportion of the post to be spaced apart from the sidewall by a distance that is at least five times the clearance gap.

Example 19 includes the apparatus of any preceding clause, wherein the first proportion corresponds to no more than half the circumference.

Example 20 includes the apparatus of any preceding clause, wherein the post is a first post, the opening is a first opening, and the clearance gap is a first clearance gap, the apparatus including a second post extending into a second opening in the heatsink, the second post having a second clearance that extends along a third proportion of a circumference of the second post, the third proportion corresponding to less than all the circumference of the second post, the first proportion being oriented relative to the first post different from how the third proportion is oriented relative to the second post.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a heatsink to be thermally coupled to an integrated circuit package on a circuit board; and
a guidepost to protrude away from the circuit board into a hole in a base of the heatsink, a clearance between an outer surface of the guidepost and an inner sidewall of the hole being less than 0.5 mm.

2. The apparatus of claim 1, including a bolster plate to surround the integrated circuit package, the guidepost connected to and protruding from the bolster plate.

3. The apparatus of claim 1, including a backplate adjacent to a back side of the circuit board, the circuit board between the backplate and the heatsink, the guidepost connected to and protruding from the backplate through the circuit board.

4. The apparatus of claim 1, wherein the guidepost has a first radius, and the inner sidewall follows a circular arc having a second radius, the clearance corresponding to a difference between the first radius and the second radius.

5. The apparatus of claim 4, wherein the circular arc extends less than 360 degrees around a circumference of the guidepost.

6. The apparatus of claim 5, wherein the circular arc extends 180 degrees or less around the circumference.

7. The apparatus of claim 4, wherein the circular arc extends at least 90 degrees around a circumference of the guidepost.

8. The apparatus of claim 1, wherein the guidepost is a first guidepost, the hole is a first hole, and the clearance is a first clearance, the apparatus including a second guidepost that is to extend into a second hole in the base of the heatsink, a second clearance between an outer surface of the second guidepost and an inner sidewall of the hole being less than 0.5 mm.

9. The apparatus of claim 8, wherein the first and second clearances are to be at complementary locations relative to the respective first and second guideposts.

10. The apparatus of claim 8, wherein both the first and second clearances are to be oriented towards a center of the base of the heatsink.

11. The apparatus of claim 1, wherein the hole is an elongated slot.

12. The apparatus of claim 11, wherein the guidepost is to be adjacent to a first end of the elongated slot.

13. The apparatus of claim 1, wherein the guidepost has a width of approximately 3 mm.

14. An apparatus comprising:
a heatsink;
a first pin to extend into a first hole in a base of the heatsink, the first pin to be a first distance from a first point along an inner sidewall of the first hole; and
a second pin rigidly fixed in position relative to the first pin, the second pin to extend through a second hole in the heatsink base, the second pin to be a second distance from a second point along an inner sidewall of the second hole, a sum of the first distance and the second distance to be less than 1 mm.

15. The apparatus of claim 14, wherein the first point is on a first side of the first pin, and the second point is on a second side of the second pin, the first side opposite to the second side.

16. The apparatus of claim 14, wherein the first pin is to be a third distance from a third point along the inner sidewall of the first hole, the third point spaced apart from the first point, the third distance greater than the first distance.

17. An apparatus comprising:
a socket mounted to a circuit board;
a bolster plate mounted on the circuit board adjacent to the socket;
a backplate coupled to the bolster plate, the circuit board between the backplate and the bolster plate;
a heatsink to be thermally coupled to an integrated circuit package in the socket; and
a post extending into opening in the heatsink, the post extending from at least one of the bolster plate or the backplate, the post having a clearance gap with a sidewall of the opening that is 0.45 mm or less.

18. The apparatus of claim 17, wherein the clearance gap is to extend along a first proportion of a circumference of the post, a second proportion of the post to be spaced apart from the sidewall by a distance that is at least five times the clearance gap.

19. The apparatus of claim 18, wherein the first proportion corresponds to no more than half the circumference.

20. The apparatus of claim 18, wherein the post is a first post, the opening is a first opening, and the clearance gap is a first clearance gap, the apparatus including a second post extending into a second opening in the heatsink, the second post having a second clearance that extends along a third proportion of a circumference of the second post, the third proportion corresponding to less than all the circumference of the second post, the first proportion being oriented relative to the first post different from how the third proportion is oriented relative to the second post.
